(19) United States
(12) Patent Application Publication
(10) Pub. No.: US 2009/0277386 A1
(43) Pub. Date: Nov. 12, 2009

(54) CATALYTIC CHEMICAL VAPOR DEPOSITION APPARATUS

(75) Inventors: Makiko Takagi, Chiba (JP); Hiromi Itoh, Chiba (JP); Kazuya Saito, Chiba (JP); Hideki Fujimoto, Shizuoka (JP)

Correspondence Address: ARENT FOX LLP, 1050 CONNECTICUT AVENUE, N.W., SUITE 400, WASHINGTON, DC, 20036, US

(73) Assignee: ULVAC, Inc., Kanagawa (JP)

(21) Appl. No.: 12/296,547

(22) PCT Filed: Apr. 9, 2007
(86) PCT No.: PCT/JP2007/057804

§ 371 Date: Feb. 3, 2009

(30) Foreign Application Priority Data
Apr. 13, 2006 (JP) 2006-110884

(51) Int. Cl. C23C 16/46

(52) U.S. Cl. 118/724

(57) ABSTRACT

A catalytic chemical vapor deposition apparatus is provided for producing a thin film of desired film quality, by making a particle countermeasure against the release gas such as H₂O and deposit materials from or on members composing the structure of the inside of the processing chamber and the inner wall of the processing chamber.

A catalytic chemical vapor deposition apparatus comprising a substrate 4 arranged in a processing chamber 1, a shower plate 7 facing the substrate 4, and a catalyst 5 comprising metal tungsten wire activating a raw material gas from the shower plate 7, where the catalyst 5 is interposed between the substrate 4 and the shower plate 7 and where a cylindrical peripheral wall 23 encloses the space where the substrate 4 and the shower plate 7 face each other in the processing chamber 1, and additionally comprising a vacuum gas discharge unit so as to make the pressure inside the cylindrical peripheral wall 23, namely the pressure in the film formation region 26 higher than that in the other region.

### TECHNICAL FIELD

The present invention relates to a catalytic chemical vapor deposition apparatus for depositing a thin film on a substrate, by decomposing a raw material gas utilizing the action of a catalyst generating heat via electricity.

### BACKGROUND OF THE INVENTION

As the film deposition method for producing various semiconductor devices and liquid crystal displays, for example, the chemical vapor deposition process (CVD process) has been used widely.

As the CVD process, for example, thermal CVD process and plasma CVD process have been known traditionally. In recent years, however, a catalytic chemical vapor deposition process (also referred to as catalytic CVD process, Cat-CVD process or hot wire CVD process) has been utilized practically, using a wire of for example tungsten heated via electricity (referred to as “catalyst” hereinafter) as the catalyst, where a raw material gas supplied into a reaction chamber is decomposed by the catalytic action of the catalyst to deposit a thin film on a substrate.

Compared with the thermal CVD process, the catalytic chemical vapor deposition process enables film formation at lower temperature. Additionally, the process never involves problems, such as the occurrence of damages on substrates due to plasma generation as in the plasma CVD process. Therefore, the catalytic chemical vapor deposition process has been drawing attention as a promising film formation technique for producing next-generation devices. Still additionally, attention has been focused on the process, since the apparatus and structure for the process is very simple. This will be described with reference to FIG. 1 as a schematic drawing depicting the general apparatus and structure of the catalytic chemical vapor deposition apparatus.

In a processing chamber 1 of the catalytic chemical vapor deposition apparatus, there are arranged a substrate-placing platform 3 with a heater 2 in the inside thereof, and a catalyst 5 comprising a metal wire at a high melting point, such as tungsten and iridium and facing a substrate 4 on the platform 3, while the catalyst 5 is connected through electric power input parts 11a, 11b to an electric power supply source 6 in the outside of the processing chamber. In the top part of the processing chamber 1, there is arranged a shower plate 7 equipped with a great number of gas nozzles 7a as arranged directly above the catalyst 5, so that the reaction gas supplied from the raw material gas supply source 8 in the outside of the processing chamber is jetted out of the gas nozzles 7a toward the catalyst 5.

In the processing chamber 1, additionally, a vacuum gas discharge mechanism 10 is arranged for discharging gas through a gas discharge outlet 9 from the inside of the processing chamber 1.

In such catalytic chemical vapor deposition apparatus, the raw material gas from the shower plate 7 is not entirely deposited as a deposited species or reaction species on the substrate 4, due to the positional relation between the shower plate 7 and the substrate 4, during film formation. Therefore, problematically, various disadvantages occur due to the raw material gas or due to the deposited species or reaction species derived from the raw material gas as never deposited on the substrate 4 or drawbacks occur due to the temperature rise, caused via heat transmission or radiant heat from the catalyst 5 heated, in the electric power input parts 11a, 11b, the members composing the inside of the processing chamber and the inner wall of the processing chamber. Thus, various propositions have been made so as to overcome these problems.

In FIG. 5 in the patent reference 1, for example, an electrical heating element CVD apparatus is shown, where a connection terminal part of an electrical heating element in connection with an electric power supply source is placed in a hollow cover, into which a purge gas is introduced to allow the purge gas to flow toward the direction of a film formation region, so as to prevent the modification of the electrical heating element at its low temperature part into silicides during the formation of a silicone film or a silicone compound film.

Otherwise, FIG. 1 in the patent reference 2 shows that a space including an electrical heating element between a raw material gas supplier and a substrate is enclosed with a heating unit to sufficiently heat the resulting film formation region, so as to prevent the inactivation of atomic hydrogen as a factor causing the occurrence of dangling bonds, when a polycrystalline silicone film is to be produced with an electrical heating element CVD apparatus.

Patent reference 1: JP-A-2002-93723 (FIG. 5)

Patent reference 2: JP-A-2003-218046 (FIG. 1)

### DISCLOSURE OF THE INVENTION

### Problems that the Invention is to Solve

Other than the silicide modification and the inactivation of atomic hydrogen, factors inhibiting desired film formation are suggested for the catalytic chemical vapor deposition apparatus. Among them, the occurrence of a contaminating substance due to the adsorbed gas molecules inside the vacuum system is particularly problematic.

Even when the inside of the vacuum chamber is surface treated cleanly, gaseous molecules such as atmospheric moisture gas may be adsorbed on the surface, if the inside is exposed to air during operations for example for substrate exchange. When the catalytic chemical vapor deposition apparatus is in operation at that state, problematically, temperature rise occurs in the electric power input parts 11a, 11b, the members composing the inside of the processing chamber and the inner wall of the processing chamber in the processing chamber 1 in FIG. 1, for example, which is caused by heat transmission or radiant heat from the catalyst 5 heated via electricity, so that the gas molecules adsorbed on such surfaces are released therefrom, disadvantageously.

When the catalyst 5 is heated via electricity in the catalytic chemical vapor deposition apparatus in FIG. 1, specifically, the adsorbed gas molecules such as H₂O as adsorbed on the surface are released from the surface, which may sometimes flow into the film formation region between the shower head 7 and the substrate 4. Consequently, the adsorbed gas molecules in influx are excited as active species, using the catalyst 5 as a medium, so that the gas molecules contaminate as impurities into the thin film formed on the substrate 4, sometimes never leading to any recovery of any thin film of desired film quality.

Furthermore, deposits derived from the raw material gas or the deposited species or reaction species thereof from the film formation region may be deposited on the surface of the member composing the inside of the processing chamber or of the inner wall of the processing chamber. The deposits may sometimes work as a source causing the generation of particles adversely affecting the resulting thin film.

The adsorbed gas molecules or the deposits may deposit on the entire surfaces of the members composing the inside of the processing chamber. Hence, the apparatus according to the patent reference 2 where items of the heating units are additionally arranged should need a countermeasure to prevent the deposition.

In view of the problems described above, in accordance with the invention, a catalytic chemical vapor deposition apparatus is provided for producing a thin film of desired film quality, by making a countermeasure against the release gas from the adsorbed gas molecules on the surface of the processing chamber, typically including H₂O and by making a particle countermeasure against the deposits due to the raw material gas, or the deposit species or reaction species thereof.

### Means for Solving the Problems

So as to solve the problems, the catalytic chemical vapor deposition apparatus of the invention comprises a substrate arranged in a processing chamber which can be vacuum discharged, a raw material gas supply source supplying a raw material gas for film formation into the processing chamber, a catalyst acting as the catalyst for the raw material gas by generating heat via electricity, and an electric power input part supplying electric power to the catalyst, to form a thin film on the substrate utilizing the action of the catalyst, where a partition unit is arranged for dividing the inside of the processing chamber at least into a film formation region where the catalyst faces the substrate and the other region and where a vacuum gas discharge unit is arranged for making the pressure in the film formation region higher than the pressures in the other region.

According to such apparatus, the pressure in the outside of the film formation region, namely the region closer to the inner wall which includes the electric power input part in the processing chamber, is lower than the pressure in the film formation region. At such lower pressure, the thermal conductivity is reduced, so that the temperature rise in the region tends to be suppressed compared with the film formation region. In the region closer to the inner wall, hence, the temperature rise through heating via electricity is suppressed, allowing not only the reduction of generated release gas due to the adsorbed gas molecules such as H₂O, but also the discharge of the generated release gas, with no invasion thereof into the film formation region. Consequently, the contamination of impurities due to the adsorbed gas molecules into the resulting thin film on the substrate is suppressed, to enable a film formation of desired film quality.

Furthermore, the catalytic chemical vapor deposition apparatus of the invention comprises the partition unit comprising a peripheral wall enclosing the film formation region, to supply the raw material gas from the raw material gas supply source to the inside of the peripheral wall and to discharge gas from the outside of the peripheral wall with the vacuum gas discharge unit.

In such manner, the region closer to the inner wall, including the electric power input part is allowed to correspond to the outside of the peripheral wall, which is discharged with the vacuum gas discharge unit, so that the amounts of the residual raw material gas, and deposited species or reaction species thereof flowing from the film formation region in the region are reduced, leading to the reduction of the amounts of deposits therein. Therefore, the occurrence of particles due to the deposits on the surface of the members composing the inside of the processing chamber and on the surface of the inner wall of the processing chamber is suppressed in the region. Additionally even when such particles emerge, the particles are discharged without the invasion thereof into the film formation region. In such way, the region can be maintained more easily.

Otherwise, the partition unit comprises a hollow body placing the electric power input part therein, where an auxiliary gas discharge unit for discharging gas from the inside of the hollow body is arranged.

In such manner, the electric power input part supplying electric power to the catalyst is separately arranged in the inside of the hollow body, while gas is discharged from the inner space thereof with an auxiliary gas discharge unit, to isolate the electric power input part from the film formation region, to maintain the difference in pressure between the peripheral region thereof and the film formation region.

Additionally, the partition unit comprises the peripheral wall enclosing the film formation region and a hollow body placing therein the electric power input part, to supply the raw material gas from the raw material gas supply source to the inside of the peripheral wall, and to discharge gas from the outside of the peripheral wall with the vacuum gas discharge unit and to discharge gas from the inside of the hollow body into vacuum with the auxiliary gas discharge unit.

Furthermore, the hollow body and the auxiliary gas discharge unit are individually arranged in each of a plurality of the electric power input part.

Even when a partition unit of either structure is used, an input unit for inputting a purge gas into a region at a relatively lower pressure among the two regions separated via the partition unit is arranged, to prevent the retention of the release gas from the adsorbed gas molecules in the region.

As the purge gas to be introduced, gases such as He, Ar, N₂, H₂, NH₃, and N₂O or mixture gases thereof may be used.

Any of the gas components is a gas component with chemically stable properties for the raw material gas such as silane gas and for the surfaces of the members composing the inside of the processing chamber.

### ADVANTAGES OF THE INVENTION

In the catalytic chemical vapor deposition apparatus of the invention, the separation of the regions with the partition unit as well as the vacuum gas discharge and purge gas introduction outside the film formation region enables the reduction of the pressure outside the film formation region compared with the pressure in the film formation region. Outside the film formation region, the temperature rise through heating of the catalyst via electricity is suppressed, to reduce the generation of the release gas from the adsorbed gas molecules such as H₂O and to discharge the release gas generated with no invasion thereof into the film formation region. Consequently, then, the contamination of impurities due to the adsorbed gas molecules into the thin film on the substrate is suppressed to enable film formation of desired film quality.

Further, the amounts of the raw material gas and deposited species or reaction species thereof are reduced due to the vacuum gas discharge or the purge gas introduction outside the film formation region, to enable the reduction of the deposition thereof in the region. Thus, the generation of particles due to the deposits on the surface on the members composing the inside of the processing chamber and on the surface of the inner wall of the processing chamber is suppressed, and additionally, the particles even when generated are discharged, without invasion into the film formation region. In such manner, the region can be maintained more easily.

### BEST MODE FOR CARRYING OUT THE INVENTION

Examples of the catalytic chemical vapor deposition apparatus of the invention are now described below. The catalytic chemical vapor deposition apparatus of the invention is the same as a general example of the catalytic chemical vapor deposition apparatus shown in FIG. 1, in terms of the outer structures of the apparatuses. Therefore, there is not shown any outer electric power supply source, any vacuum gas discharge unit, or any partition valve.

### EXAMPLE 1

FIG. 2 is a schematic view depicting a first example of the catalytic chemical vapor deposition apparatus of the invention. Like the general catalytic chemical vapor deposition apparatus shown in FIG. 1, a substrate-placing platform 3 including a heater 2 therein, and a catalyst 5 comprising metal tungsten wire or metal iridium wire in the processing chamber 21, where the catalyst 5 is arranged in a manner such that the catalyst faces the substrate 4 on the placing platform 3. On the placing platform 3 are mounted ascent and descent pins 3a, 3b for receiving and transferring the substrate 4 during transfer. The catalyst 5 is supported and drawn with a tension with electric power input parts 11a, 11b arranged throughout the inner walls 21a, 21b facing each other.

On the inner wall 21c in the upper part of the processing chamber 21, a shower plate 7 equipped with a great number of gas nozzles 7a is arranged at a position directly above the catalyst 5, for jetting the raw material gas and a carrier gas through the gas nozzles 7a from the raw material gas supply source 8 toward the direction of the catalyst 5 and the substrate 4. By enclosing the region (film formation region) where the shower plate 7 and the substrate 4 face each other, with a cylindrical peripheral wall 23, further, the region is partitioned spatially. So as to discharge gas from the outside of the cylindrical peripheral wall 23, a gas discharge outlet 22 is arranged at a position closer to the side wall of the processing chamber on the inner wall 21d opposing the inner wall 21c, where the shower plate 7 is arranged.

Since a constant down-flow from the shower plate 7 toward the direction of the substrate 4 is thereby established in the processing chamber 21, the raw material gas and the carrier gas reach the substrate 4, while the gases are in contact with the catalyst 5 along the down-flow.

So as to monitor the pressure in the inside of the cylindrical peripheral wall 23, namely in the film formation region 26, additionally, a vacuum meter 24 is arranged. So as to make a purge gas flow in the outer region 27 of the cylindrical peripheral wall 23, a purge gas inlet 25 is arranged.

For preparing films such as silicone film, using the catalytic chemical vapor deposition apparatus of such structure, a raw material gas and a carrier gas are introduced in the film formation region 26 spatially separated with the cylindrical peripheral wall 23, so that the pressure therein is relatively higher than that in the outer region 27. In other words, gas is discharged from the outer region 27 including the electric power input parts 11a, 11b individually arranged on the inner walls 21a, 21b, respectively, with a vacuum gas discharge unit not shown in figures through the gas discharge outlet 22 arranged in the region 27. Consequently, the pressure in the outer region 27 is relatively lower than that in the film formation region 26.

Even during heating via electricity in the catalyst 5, therefore, temperature rise is suppressed in the electric power input parts 11a, 11b, the inner walls 21a through 21d, or parts belonging to the region 27 on the substrate-placing platform 3, as described above. Thus, the release gas from the adsorbed gas molecules such as H₂O adsorbed on the surfaces of them is reduced. Consequently, the invasion of impurities due to these adsorbed gas molecules into the proximity of the substrate 4 is suppressed. In such manner, a film of desired film quality can be prepared.

Because gas is constantly discharged in the outer region 27, the retention amount of the raw material gas, deposit species thereof or reaction species thereof flowing from the film formation region 26 is so less that the amount of unnecessary films deposited can be reduced. As a result, the amount of particles generated due to deposits on the surface of the members composing the inside of the region 27 (such as the electric power input parts 11a, 11b, and the substrate-placing platform 3) and the surface of the inner walls 21a through 21d is reduced. Furthermore, periodical maintenance can be done more easily.

Additionally, gases such as Ar and N₂ may be introduced as the purge gas from the purge gas inlet 25. In the region 27, the purge gas prevents the retention of the release gas from the adsorbed gas molecules on the surface of the members composing the inside thereof in the region. Further, discharge of the raw material gas, deposit species thereof or reaction species thereof is promoted, without any influence on the film formation region 26, even when such particles are generated.

Essentially, the purge gas introduced works as a factor for reducing the difference in pressure between the film formation region 26 and the outer region 27. Therefore, preferably, the purge gas is introduced under monitoring of the difference in pressure between the two regions, with a pressure monitor such as the vacuum meter 24.

By making the purge gas sufficiently flow during the preparation of films such as silicone film, then, the modification of the catalyst into silicides due to the raw material gas such as silane gas can effectively be prevented.

As the purge gas to be introduced from the purge gas inlet 25, there may be used gases such as He, Ar, N₂, H₂, NH₃, and N₂O or mixture gases thereof. Even any component gas other than these gases may be used, when the gas has chemically stable properties for the raw material gas such as silane gas and the members composing the inside of the processing chamber.

### EXAMPLE 2

FIG. 3 is a schematic view of the essential part depicting a second example of the catalytic chemical vapor deposition apparatus of the invention, showing a catalyst wire-fixing frame 31 as an example for mounting the catalyst 5 and the electric power input parts 11a, 11b in the catalytic chemical vapor deposition apparatus shown in FIGS. 1 and 2.

In FIG. 3, the catalyst 5 is in direct connection with an outer electric power supply source 32. On the turn point thereof, the catalyst 5 is supported and fixed on the frame 31, with a support terminal 33. Both the ends 5b, 5b of the catalyst 5 are connected through connection terminals 34, 34 also working as support terminals for the frame 31 with the outer electric power supply source 32.

Then, the support terminal 33 and the connection terminal 34 as arranged on plural positions are individually covered with a hollow cover 35, while a gas discharge tube 36 in connection with an auxiliary gas discharge unit (not shown in figures) for discharging gas from the inside of the hollow cover 35 is arranged on each of the terminals.

The catalyst wire-fixing frame 31 in such structure is mounted along the inner wall on the position where the catalyst wire is drawn with a tension in the processing chamber 1 of the catalytic chemical vapor deposition apparatus shown in FIG. 1. While continuously discharging gas from the inside of the hollow cover 35 through the gas discharge tube 36, the raw material gas and the carrier gas are allowed to flow in the film formation region 37 outside the hollow cover 35, while the catalyst 5 is heated via electricity, to prepare films such as silicone film.

Because gas is discharged from the inside of the hollow cover 35 placing therein the support terminal 33 and the connection terminal 34 through the gas discharge tube 36, then, any release gas even when generated inside the hollow cover 35 is never released into the film formation region 37 at a higher pressure. Even when the raw material gas and the like in the film formation region 37 flow from the space for leading the catalyst 5 outside in the hollow cover 35, into the inside of the hollow cover 35 due to the pressure difference, the gases can be discharged immediately, without any disadvantages on the connection part on the catalyst 5.

### EXAMPLE 3

FIG. 4 is a schematic view of the essential part depicting a third example of the catalytic chemical vapor deposition apparatus of the invention. In the catalyst wire-fixing frame 31 shown in FIG. 3, the hollow cover 35 is arranged for each of the support terminal 33 and the connection terminal 34. However, the hollow cover 45 in the third example is in an integral structure for placing collectively the support terminal 33 or connection terminal 34 arranged on the same side on the frame 31. Simultaneously, the gas discharge tube 46 for discharging gas from the inside of the hollow cover 45 may comprise a single gas discharge tube.

By employing such structure for coordinated use, the structure of the apparatus is made simpler, while the pressure control in the inside of the hollow cover 45 toward the film formation region 37 can be done more easily.

### EXAMPLE 4

FIG. 5 is a schematic view of the essential part depicting a fourth example of the catalytic chemical vapor deposition apparatus of the invention, where a purge gas inlet tube 55 is arranged in the hollow cover 45 in such an integral structure as in FIG. 4.

According to the Example, as in the Example 2, gas is discharged from the inside of the hollow cover 45 placing therein the support terminal 33 and the connection terminal 34, so that the pressure in the hollow cover 45 is maintained at a lower value, to suppress the generation of the release gas. By introducing gases such as Ar and N₂ as purge gas through a purge gas inlet tube 55 as in Example 1, any raw material gas, deposit species or reaction species thereof are discharged immediately even when they flow from the space for leading the catalyst 5 outside in the hollow cover 45, into the inside of the hollow cover 45. Even when particles are generated in the hollow cover 45, the particles can be discharged without any influence on the film formation region 37.

By allowing sufficient flow of the purge gas during the preparation of films such as silicone film, further, the modification of the catalyst into silicides due to the raw material gas such as silane gas can effectively be prevented.

As the purge gas to be introduced from the purge gas inlet tube 55, there may be used gases such as He, Ar, N₂, H₂, NH₃, and N₂O or mixture gases thereof, as in Example 1.

In the above Examples, examples of enclosing the film formation region 26 with the cylindrical peripheral wall 23 and examples where the support terminal 33 of the catalyst 5 and the connection terminal 34 thereof are separately placed in the hollow covers 35, 45, are individually described. However, these examples may be used in combination.

### EXAMPLE 5

FIG. 6 is a schematic view depicting a fifth example of the catalytic chemical vapor deposition apparatus of the invention. The apparatus differs in structure from the catalytic chemical vapor deposition apparatus of Example 1, as shown in FIG. 2, in that the apparatus is used as a reel-up film formation apparatus using a substrate 64 of a long film. In the processing chamber 61 of the reel-up catalytic chemical vapor deposition apparatus, the film reel-up procedures allow the substrate 64 to move following the rotation of a water-chilled can 62, for continuous film formation.

As in Example 1, a catalyst 5 comprising metal tungsten wire or metal iridium wire arranged in a manner such that the catalyst 5 faces the surface of the substrate 64 to be treated are supported and drawn with a tension, with electric power input parts 11a, 11b arranged throughout the inner walls 61a, 61b facing each other; the region (film formation region) where a shower plate 67 faces the surface of the substrate 64 to be treated is spatially separated by enclosing the region with a cylindrical peripheral wall 63; a gas discharge outlet 22 is arranged for discharging gas from the outside of a cylindrical peripheral wall 63; a vacuum meter 74 is arranged for monitoring the pressure in the inside of the cylindrical peripheral wall 63, namely the film formation region 66; a purge gas inlet 65 is arranged on the outer region 67 of the cylindrical peripheral wall 63 for allowing a purge gas to flow.

The procedures for preparing films such as silicone film using the reel-up catalytic chemical vapor deposition apparatus as well as the actions thereof are the same as in Example 1, except that the substrate 64 of a long film moves following the rotation of the water-chilled can 62 during the treatment of film formation.

### BRIEF DESCRIPTION OF THE DRAWINGS

FIG. 1 A schematic view depicting the apparatus and structure of the general catalytic chemical vapor deposition apparatus.

FIG. 2 A schematic view depicting the apparatus and structure of a first example of the catalytic chemical vapor deposition apparatus of the invention.

FIG. 3 A schematic view depicting an example of the essential part in a second example of the catalytic chemical vapor deposition apparatus of the invention.

FIG. 4 A schematic view depicting an example of the essential part in a third example of the catalytic chemical vapor deposition apparatus of the invention.

FIG. 5 schematic view depicting an example of the essential part in a fourth example of the catalytic chemical vapor deposition apparatus of the invention.

FIG. 6 A schematic view depicting the apparatus and structure of a fifth example of the catalytic chemical vapor deposition apparatus of the invention.

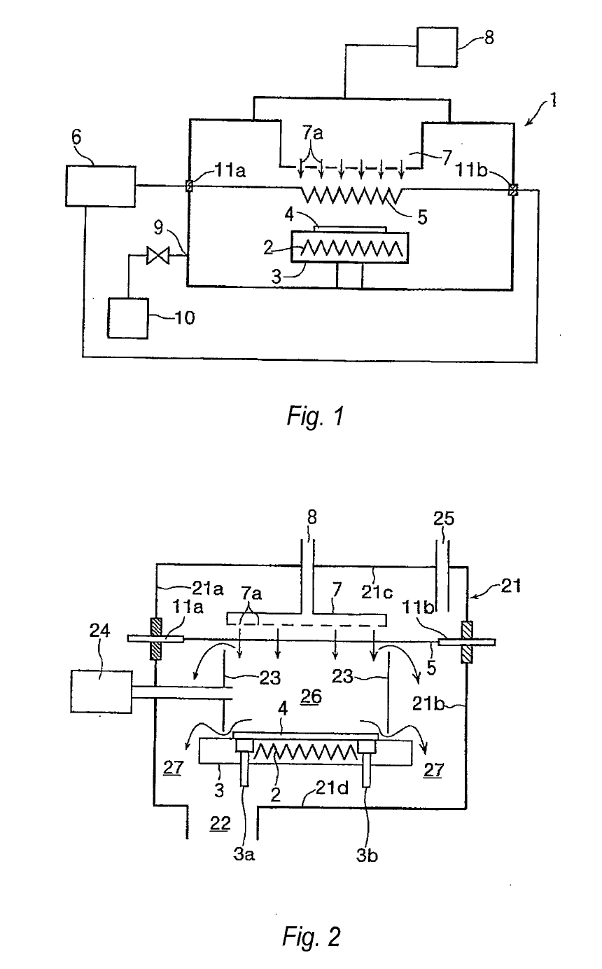

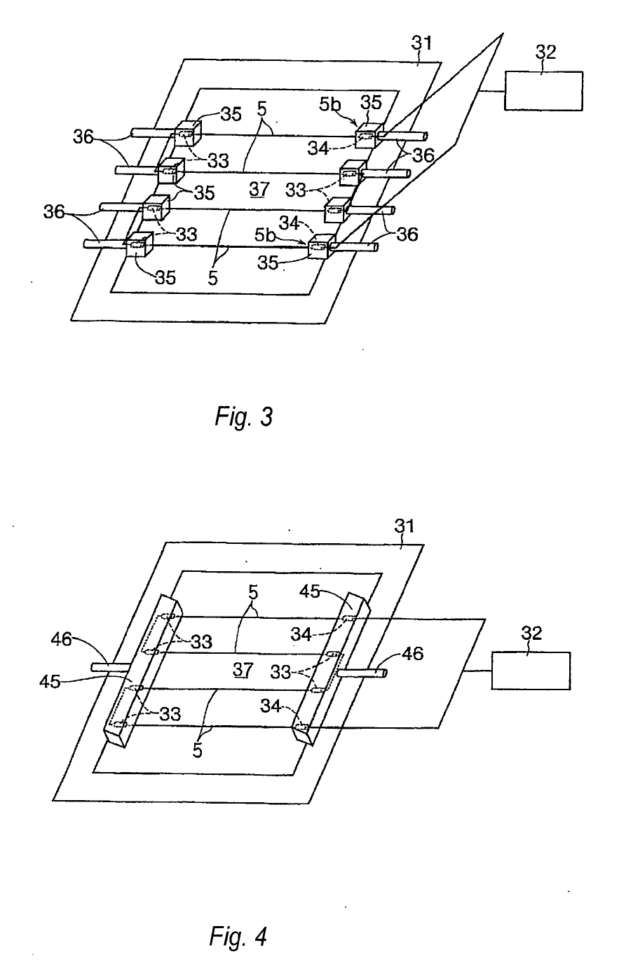

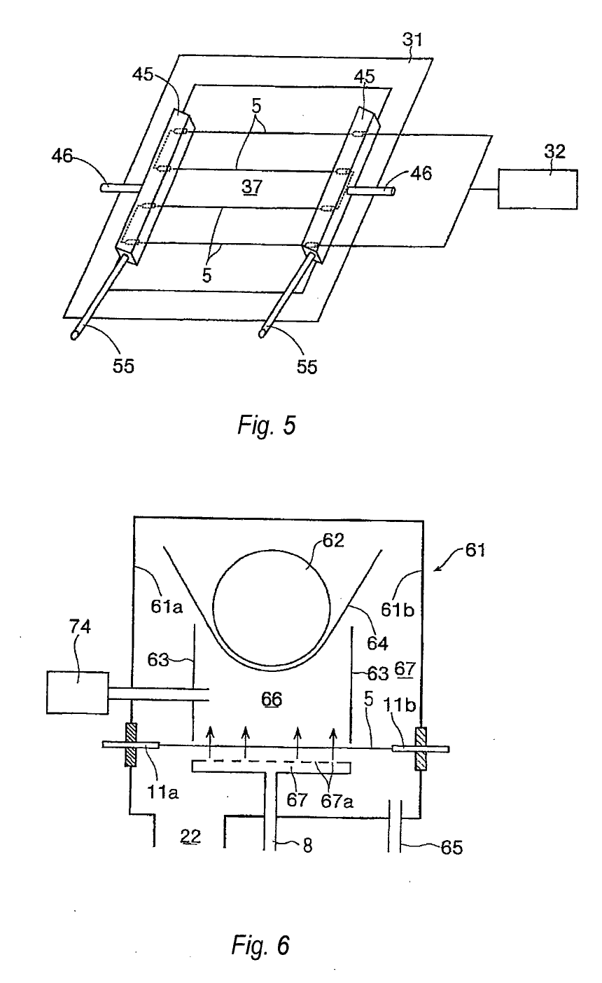

1. A catalytic chemical vapor deposition apparatus comprising a substrate arranged in a processing chamber which can be vacuum discharged, a raw material gas supply source supplying a raw material gas for film formation into the processing chamber, a catalyst acting as a catalyst for the raw material gas by generating heat via electricity and an electric power input part supplying electric power to the catalyst, to form a thin film on the substrate utilizing the action of the catalyst, where a partition unit is arranged for dividing the inside of the processing chamber at least into a film formation region where the catalyst faces the substrate and the other region and where a vacuum gas discharge unit is arranged for making the pressure in the film formation region higher than the pressures in the other regions.

2. A catalytic chemical vapor deposition apparatus according to claim 1, where the partition unit comprises a peripheral wall enclosing the film formation region, to supply the raw material gas from the raw material gas supply source to the inside of the peripheral wall and to discharge gas from the outside of the peripheral wall with the vacuum gas discharge unit.

3. A catalytic chemical vapor deposition apparatus according to claim 1, where the partition unit comprises a hollow body placing the electric power input part therein, where an auxiliary gas discharge unit for discharging gas from the inside of the hollow body is arranged.

4. A catalytic chemical vapor deposition apparatus according to claim 1, where the partition unit comprises a peripheral wall enclosing the film formation region and a hollow body placing therein the electric power input part, to supply the raw material gas from the raw material gas supply source to the inside of the peripheral wall, and to discharge gas from the outside of the peripheral wall with the vacuum gas discharge unit and to discharge gas from the inside of the hollow body into vacuum with then auxiliary gas discharge unit.

5. A catalytic chemical vapor deposition apparatus according to claim 3 or 4, where the hollow body and the auxiliary gas discharge unit are individually arranged in each of a plurality of the electric power input part.

6. A catalytic chemical vapor deposition apparatus according to any one of claims 1, 2 and 4, where an input unit for inputting a purge gas into the outside of the peripheral wall is arranged.

7. A catalytic chemical vapor deposition apparatus according to any one of claims 3 through 4, where an input unit for inputting a purge gas into the hollow body is arranged.

8. A catalytic chemical vapor deposition apparatus according to claim 6, where the purge gas to be introduced is a gas such as He, Ar, N₂, H₂, NH₃, and N₂O or a mixture gas thereof.
